(19) United States
(12) Patent Application Publication
(10) Pub. No.: US 2012/0319242 A1
(43) Pub. Date: Dec. 20, 2012

(54) Dopant Implantation Hardmask for Forming Doped Isolation Regions in Image Sensors

(76) Inventors: Duli Mao, Sunnyvale, CA (US); Hsin-Chih Tai, Cupertino, CA (US); Vincent Venezia, Sunnyvale, CA (US); Keh-Chiang Ku, Cupertino, CA (US); Yin Qian, Milpitas, CA (US); Gang Chen, San Jose, CA (US); Rongsheng Yang, San Jose, CA (US); Howard Rhodes, San Martin, CA (US)

(21) Appl. No.: 13/164,563

(22) Filed: Jun. 20, 2011

(51) Int. Cl. H01L 29/02; H01L 31/02

(52) U.S. Cl. 257/544; 438/73; 438/57; 257/431; 257/E31.11; 257/E29.002

(57) ABSTRACT

Forming a doped isolation region in a substrate during manufacture of an image sensor. A method of an aspect includes forming a hardmask layer over the substrate, and forming a photoresist layer over the hardmask layer. An opening is formed in the photoresist layer over an intended location of the doped isolation region. An opening is etched in the hardmask layer by exposing the hardmask layer to one or more etchants through the opening. The opening in the hardmask layer may have a width of less than 0.4 micrometers. The doped isolation region may be formed in the substrate beneath the opening in the hardmask layer by performing a dopant implantation that introduces dopant through the opening in the hardmask layer. The method of an aspect may include forming sidewall spacers on sidewalls of the opening in the hardmask layer and using the sidewall spacers as a dopant implantation mask.

### BACKGROUND

1. Field

This disclosure relates generally to doped isolation regions, and in particular but not exclusively, relates to forming doped isolation regions for image sensors.

2. Background Information

Image sensors typically include pixel arrays that include isolation regions between adjacent pixels in order to help electrically isolate or insulate the adjacent pixels from one another. FIG. 1 is a cross-sectional side view of a simple two-pixel example of a pixel array 100 that includes isolation regions 103. The pixel array has a first pixel 102-1 and a second pixel 102-2. The pixels are formed within a substrate 101. The pixel array also includes a first isolation region 103-1, a second isolation region 103-2, and a third isolation region 103-3. As shown, the second isolation region 103-2 is disposed between the first and second pixels 102-1, 102-2. Similarly, the first isolation region 103-1 may be disposed between the first pixel 102-1 and another pixel (not shown) that is positioned to the left of the first pixel, and the third isolation region 103-3 may be disposed between the second pixel 102-2 and another pixel (not shown) that is positioned to the right of the second pixel.

Each of the first, second, and third isolation regions includes a corresponding doped isolation region 104-1, 104-2, 104-3, and corresponding shallow trench isolation (STI) 105-1, 105-2, 105-3. The doped isolation regions represent doped regions or wells formed within the substrate 101 that include a dopant of a type operable to make doped isolation regions which electrically separate the photogenerated carriers of adjacent pixels. The doped isolation regions begin near the upper surface of the substrate and typically extend deep into the substrate in order to improve the amount of isolation of the adjacent pixels. The STIs represent trenches in the doped isolation regions that are typically filled with an insulating or dielectric material. Where STI structures are present the isolation regions serve to separate the photogenerated carriers from the STI regions.

Over the years the size of the pixels in image sensors has decreased significantly. The reduction in the size of the pixels has been motivated in part by factors such as a desire to provide increased image sensor resolution, reduced image sensor size, reduced image sensor manufacturing costs, reduced image sensor power consumption, and the like. Further reductions in the sizes of the pixels are desirable. One way to further reduce the size of the pixels is to reduce the size of the isolation regions 103 and/or the size of the doped isolation regions 104. However, the known method used to form these doped isolation regions tends to limit further reductions in their size.

FIGS. 2A-2C are cross-sectional side views of substrates representing different stages of a known method of forming a doped isolation region 204 in a semiconductor substrate 201 during the manufacture of an image sensor. FIG. 2A shows a thin silicon dioxide layer 206 formed over a top major surface of the semiconductor substrate 201. FIG. 2B shows a patterned thick photoresist layer 207 formed over the silicon dioxide layer 206. The patterned thick photoresist layer has a trench or other opening 208 formed therein. As shown, the trench has a cross-sectional width W1.

FIG. 2C shows forming the doped isolation region 204 in the semiconductor substrate 201. The doped isolation region is formed by introducing dopant 210 into the semiconductor substrate through the opening 208. Commonly, the doped isolation region is formed deeply into the semiconductor substrate in order to improve the amount of isolation between adjacent pixels that are to be subsequently formed on opposite sides of the doped isolation region. In order to form the doped isolation region deeply within the semiconductor substrate, a high energy dopant implantation process 209 is typically used. Representatively, the high energy dopant implantation process may use an implant energy of at least about one million electron volts (MeV) to around several million electron volts (MeV) to accelerate dopant ions toward substrate 201 such that they are carried deep into substrate 201. The implant energy is one of the main factors determining the depth to which dopant ions are placed beneath the surface of substrate 201.

One potential drawback to the aforementioned method of forming the doped isolation region 204 is that the thick patterned photoresist layer 207, with a thickness greater than desirable, is typically needed in order to stop implantation of additional dopant 211 into unintended regions of the semiconductor substrate outside of the doped isolation region. If this additional dopant 211 is not stopped it could lead to defects and/or reduced image sensor performance. However, although photoresist provides a convenient masking medium, the inherent ability of the photoresist material to stop the implant of the dopant is limited, and consequently the photoresist layer 207 often needs to be undesirably thick. One resulting challenge is that it tends to be relatively difficult to photolithographically pattern the opening 208 with small widths desired for present day very small pixels, in such a thick photoresist layer 207. This is especially true when the width of the opening 208 approaches 0.4 micrometers (μm), or less and/or when high energy dopant implantations using around one to several million electron volts (MeV) are used, which motivate the use of a thick layer. As a result, one potential drawback with this known method of doped isolation region formation is that the relatively thick photoresist layer 207 may tend to limit further size reductions of the opening 208 and/or the doped isolation region, which may limit further pixel size reductions.

Another potential drawback to using the patterned photoresist layer 207 to mask the dopant implantation is that a profile and/or shape of the opening 208 may tend to change during one or more of baking, development, and/or during the initial stages of dopant implantation. Photoresists are typically relatively “soft” materials such as organic polymeric materials that may not retain the shape of the trench or opening as much as desired when subjected to baking, development, and/or dopant implantation. For example, the vertical sidewalls of the opening 208 may tend to deform or change shape from its initial or intended shape. This may unintentionally alter the size, shape, or dopant concentrations of the doped isolation region 204.

Yet another potential drawback to using the patterned photoresist layer 207 to mask the dopant implantation is that the dopant implantation process may make the photoresist layer relatively difficult to strip away or otherwise remove. This may be especially true the case of high energy dopant implantation where the high energy ion bombardment may tend to bind or adhere the photoresist to underlying layers or materials.

Accordingly, other methods of forming doped isolation regions in semiconductor substrates would be useful.

### BRIEF DESCRIPTION OF THE SEVERAL VIEWS OF THE DRAWINGS

The invention may best be understood by referring to the following description and accompanying drawings that are used to illustrate embodiments of the invention. In the drawings:

FIG. 1 is a cross-sectional side view of a simple two-pixel example of a pixel array that includes isolation regions.

FIGS. 2A-2C are cross-sectional side views of substrates representing different stages of a known method of forming a doped isolation region in a semiconductor substrate using an opening in a thick photoresist layer to allow introduction of dopant.

FIGS. 3A-3H are cross-sectional side views of substrates representing different stages of an example embodiment of a method of forming a doped isolation region in a semiconductor substrate using an opening in a hardmask layer to allow introduction of dopant.

FIG. 4 is a block flow diagram of an example embodiment of a method of forming a doped isolation region in a substrate using an opening in a hardmask layer to allow introduction of dopant.

FIGS. 5A-5C are cross-sectional side views of substrates representing different stages of an example embodiment of a method of forming a doped isolation region in a semiconductor substrate that includes forming sidewall spacers on vertical sidewalls of an opening and using the sidewall spacers to define the region where dopant is introduced.

FIG. 6 is a cross-sectional view of a substrate showing an example embodiment of a use of a patterned hardmask layer when doping a semiconductor substrate to form a deep doped well of a photodiode.

FIG. 7 is a block diagram of an example embodiment of an image sensor system having a pixel array that may be manufactured by approaches disclosed herein,

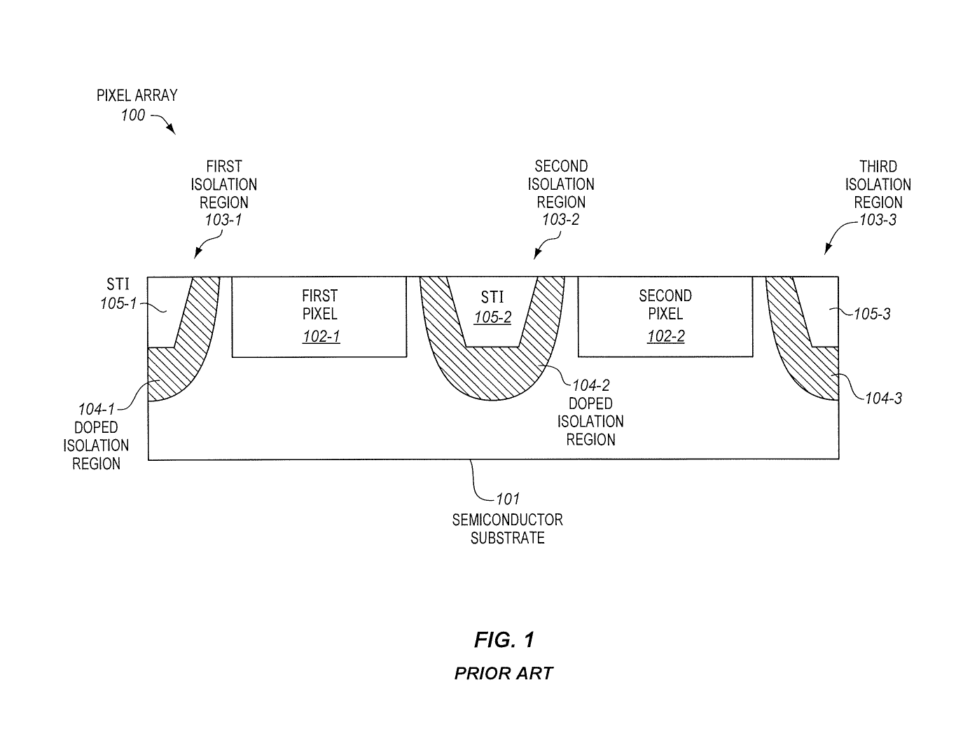

### DETAILED DESCRIPTION

In the following description, numerous specific details are set forth. However, it is understood that embodiments of the invention may be practiced without these specific details. In other instances, well-known circuits, structures and techniques have not been shown in detail in order not to obscure the understanding of this description.

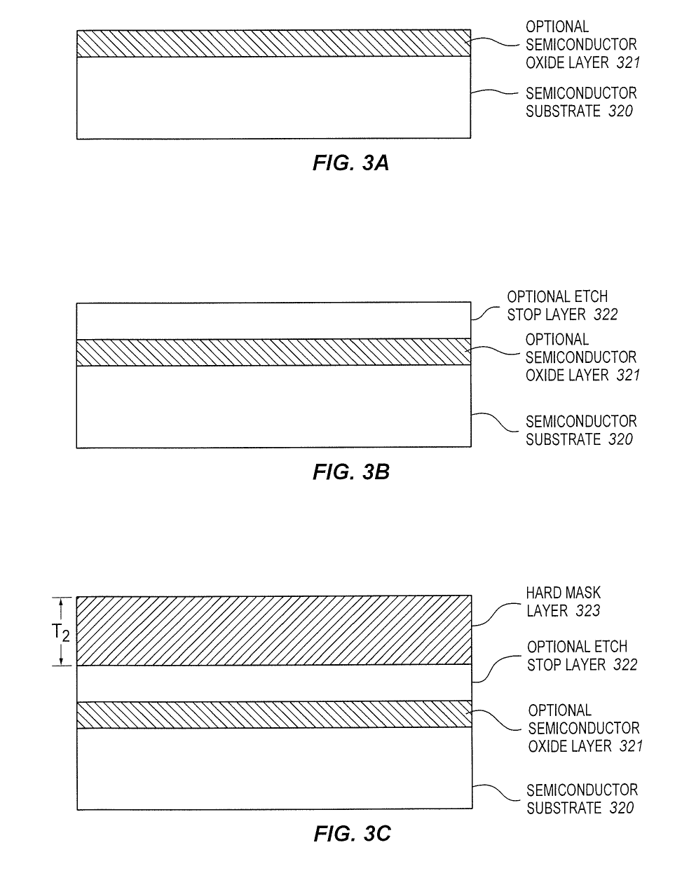

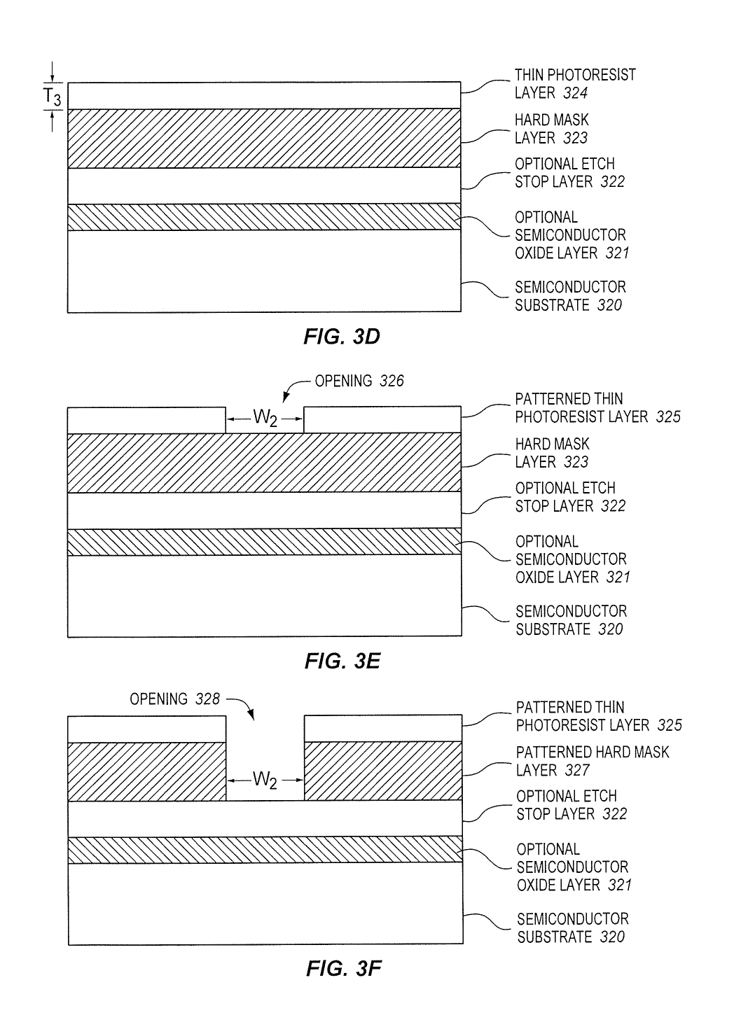

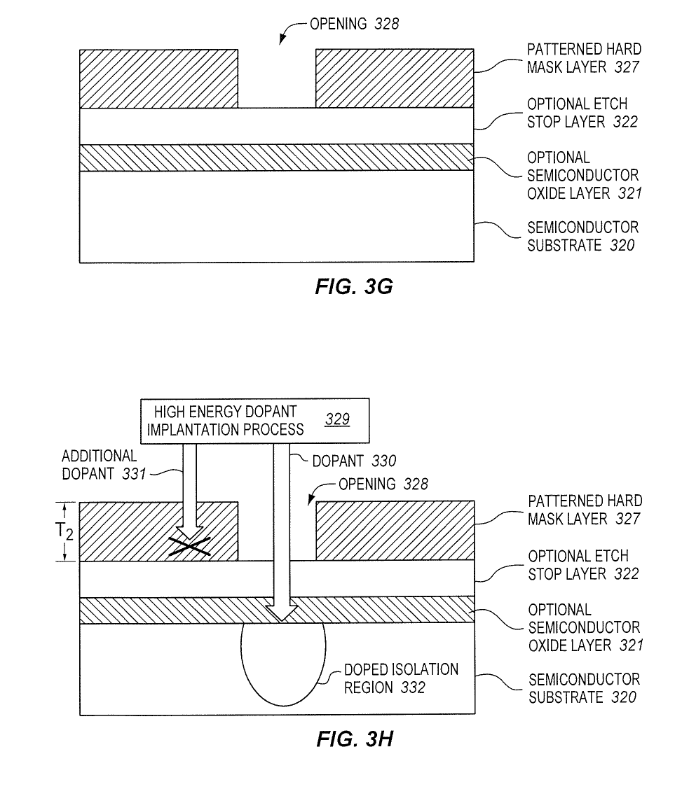

FIGS. 3A-3H are cross-sectional side views of substrates representing different stages of an example embodiment of a method of forming a doped isolation region 332 in a semiconductor substrate 320. In some embodiments, the method may be performed during the manufacture of an image sensor. The method may be used to form either a front side illuminated (FSI) or back side illuminated (BSI) image sensor. In the case of either a FSI or BSI image sensor, the doped isolation regions may optionally be doped from the front side of the semiconductor substrate.

FIG. 3A shows forming an optional thin semiconductor oxide layer 321 over a top major surface of the semiconductor substrate 320. The semiconductor oxide layer includes an oxide of a semiconductor. The thin semiconductor oxide layer may be formed by depositing an oxide of a semiconductor, growing an oxide of a semiconductor, or a combination thereof. In one embodiment, a top major surface of the semiconductor substrate 320 includes silicon, and the oxide of the semiconductor includes silicon dioxide (SiO₂) that is grown from the silicon of the semiconductor substrate.

FIG. 3B shows forming an embodiment of an optional etch stop layer 322 over the thin semiconductor oxide layer 321. As will be described further below, the etch stop layer may help to stop an etch that is performed on a subsequently formed, overlying layer. The etch stop layer is optional and not required.

FIG. 3C shows forming an embodiment of a hardmask layer 323 over the optional etch stop layer 322 and/or over the semiconductor substrate 320. The hardmask layer includes a relatively “hard” material that is relatively harder than the “soft” organic polymeric materials typically used for resists. Typically, the hardmask layer includes, is predominantly, or is substantially all, inorganic solid material (as opposed to organic polymeric material). The inorganic solid material may be amorphous, crystalline, or a combination of amorphous and crystalline materials. In one embodiment, a substantially amorphous hardmask material may be used in order to provide better stopping power for implanted dopants or ions. As used herein, a substantially amorphous hardmask material or layer is one having less than 30% crystalline material by volume.

Examples of suitable materials for the hardmask layer include, but are not limited to, semiconductors (e.g., silicon), amorphous semiconductors (e.g., amorphous silicon), polysilicon, oxides of semiconductors (e.g., silicon dioxide and other oxides of silicon), nitrides of semiconductors (e.g., silicon nitride and other nitrides of silicon), oxy-nitrides of semiconductors (e.g., oxy-nitrides of silicon), glasses, spin-on glasses, metals, metal nitrides, metal oxides, metal oxy-nitrides, etc., and combinations thereof. In some embodiments, the hardmask layer may include one or more of a layer of an oxide of silicon and a layer of amorphous silicon (e.g., a layer of polysilicon), and the etch stop layer 322 may include a nitride of silicon. If desired, multiple of such materials may be mixed or combined within the same layer and/or multiple different layers each having a different type of material may optionally be used.

The hardmask layer 323 may be formed over the semiconductor substrate by conventional approaches, such as, for example, chemical vapor deposition (CVD), physical vapor deposition (PVD), atomic layer deposition (ALD), spin-on processes, etc., depending upon the particular material. The thickness of the hardmask layer should be sufficient to prevent dopant from being implanted in unintended regions of the semiconductor substrate other than the intended dopant isolation regions by the associated dopant implantation process. Typically, the thickness of the hardmask layer 323 may be reduced compared to the thickness of the thick photoresist layer 207, since the hardmask layer typically has a greater dopant implantation stopping power. As one example, the thickness of a silicon dioxide layer suitable for a high energy boron dopant implantation using 1 MeV is about 2 μm. As another example, the thickness of a polysilicon layer suitable for a high energy boron dopant implantation using 1 MeV is about 2 μm. By way of comparison, the thickness of a photoresist layer suitable for a high energy boron dopant implantation using 1 MeV is about 3 μm.

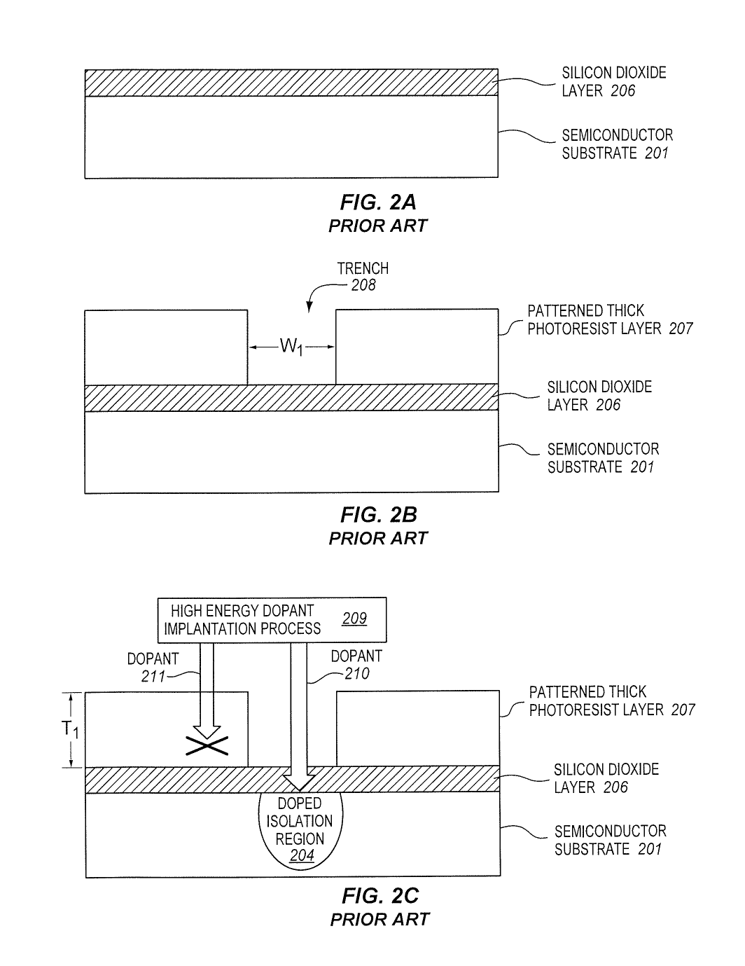

FIG. 3D shows forming a thin photoresist layer 324 over the hardmask layer 323. The thin photoresist layer may be formed by dispensing and spinning or otherwise depositing a photoresist material over the hardmask layer. The thin photoresist layer may have a conventional thickness of a typical photoresist layer, which is typically significantly thinner than the thick patterned photoresist layer 207 shown in FIG. 2B. In one aspect, the thickness need not be more than about one micrometer.

FIG. 3E shows patterning or otherwise forming a trench or other opening 326 to form a patterned thin photoresist layer 325. The opening may be formed photolithographically in the thin photoresist layer 324. For example, a lithographic exposure through a lithography mask may be used to pattern the opening in the photoresist layer, the exposed photoresist layer may then optionally be baked, and then the exposed photoresist layer may be developed in order to remove a portion of the photoresist layer corresponding to the opening. The portion removed may either be an exposed portion or an unexposed portion depending upon the type of resist.

As shown, the trench or other opening may have a cross-sectional width W2. In some embodiments, the width W2 may be less than about 0.4 μm, less than about 0.3 μm, less than about 0.25 μm, or less than about 0.2 μm. In one embodiment, the width W2 may range between about 0.2 μm to about 0.4 μm. The reduced thickness of the photoresist layer 325 compared to that of the thick photoresist layer 207 may help to facilitate the formation of such small openings. However, the scope of the invention is not limited to forming such small openings.

FIG. 3F shows etching a trench or other opening 328 in the hardmask layer 323 to form a patterned hardmask layer 327 by exposing the hardmask layer 323 to one or more etchants through the opening 326 in the patterned photoresist layer 325. The etching of the opening in the hardmask layer may include contacting or exposing a top surface of the hardmask layer exposed by and coextensive with the opening 326 to one or more etchants. Depending upon the particular hardmask layer, the etchants may include one or more solutions, one or more gases, one or more plasmas, or a combination thereof, which are sufficient to etch or remove material of the hardmask layer. The opening 326 in the patterned thin resist layer is used to allow entry of the etching medium and the width W2 may be approximately reproduced into the opening 328 in the patterned hardmask layer 327.

As one specific example, in an embodiment where the hardmask layer is a silicon dioxide layer, the trench may be etched by an etchant that is flourine ion based. As another specific example, in an embodiment where the hardmask layer is a polysilicon layer, the trench may be etched by an etchant that is bromine ion based or chlorine ion based. Other etchants suitable for etching other materials mentioned above that are suitable for the hardmask layer are known in the arts and can be readily selected by those skilled in the art and having the benefit of the present disclosure.

As shown, the opening 328 may be etched through substantially an entire thickness of the hardmask layer 327, and stop at or near the top surface of the etch stop layer 322. The etch stop layer is operable to facilitate stopping the etch. For example, the etch stop layer may have a greater etch resistance to that particular etch than the hardmask layer (e.g., the etch rate of the etch stop layer may be less than the etch rate of the hardmask layer). However, the etch stop layer is optional and not required. Precise control over the timing of the etch and/or accurate etch endpoint detection may alternatively be used to stop the etch at an appropriate time without the etch stop layer. Moreover, for certain materials suitable for the hardmask layer the semiconductor oxide layer 321 may provide a sufficient etch stop, such that the etch stop layer may be omitted.

FIG. 3G shows optionally removing the patterned thin photoresist layer 325 from over the top surface of the patterned hardmask layer 327. By way of example, the thin patterned photoresist layer may be removed by conventional resist stripping approaches. Removing the thin photoresist layer 325 prior to dopant implantation may be favored, since the photoresist tends to be easier to remove before the dopant implantation than after because the dopant implantation tends to adhere the photoresist to the underlying material. However, in an alternate embodiment the patterned thin photoresist layer 325 may be left to remain on the patterned hardmask layer during the subsequent dopant introduction process.

FIG. 3H shows forming the doped isolation region 322 in the semiconductor substrate 320 beneath the opening 328 in the patterned hardmask layer 327 by performing a dopant implantation that introduces dopant through the opening 328 in the patterned hardmask layer 327. Dopant may be introduced into the top surface of the semiconductor substrate approximately bounded by the vertical sidewalls of the opening in the patterned hardmask layer and elsewhere the dopant may be masked by remaining portions of the patterned hardmask layer. The vertical sidewalls may represent etched surfaces of solid inorganic material, and typically may retain their profile better than a photoresist.

As is known, a semiconductor may be doped with a dopant to alter its electrical properties. Dopants may either be acceptors or donors. Acceptor dopant elements generate excess holes in the semiconductor whose atoms they replace by accepting electrons from those semiconductor atoms. Suitable acceptors for silicon include boron, indium, gallium, aluminum, and combinations thereof. Donor dopant elements generate excess electrons in the semiconductor whose atoms they replace by donating electrons to semiconductor atoms. Suitable donors for silicon include phosphorous, arsenic, antimony, and combinations thereof. A “p-type semiconductor”, a “semiconductor of p-type conductivity”, or the like, refers to a semiconductor doped with an acceptor, and in which the concentration of holes is greater than the concentration of free electrons. An “n-type semiconductor”, a “semiconductor of n-type conductivity”, or the like, refers to a semiconductor doped with a donor and in which the concentration of free electrons is greater than the concentration of holes. In one embodiment, the doped isolation regions are doped to be p-type semiconductors or semiconductors of p-type conductivity. For example, they may be doped with boron.

In some embodiments, a high energy dopant implantation process 329 may be used to implant dopant 330 into the doped isolation region through the opening 328 in order to from the doped isolation region deeply below the top surface of the semiconductor substrate. Representatively, the high energy dopant implantation process may use at least about one million electron volts (MeV) to around several million electron volts (MeV) with a projection range of several micrometers, although the scope of the invention is not so limited. As used herein, at least about 1 Mev means at least 0.85 MeV. In one particular example embodiment, the implantation energy may be 1 MeV and the dose may range between 10¹³ ions/cm² to 10¹⁵ ions/cm². In some embodiments, the implanted ions may optionally be multiply charged ions.

The patterned hardmask layer may stop additional dopant 331 from entering unintended regions of the semiconductor substrate. The hard material of the patterned hardmask layer 327 often has a greater inherent ability to stop implantation of dopant than the soft material of the thick photoresist layer 207. For example, the dopant implantation stopping power of the hard material is often at least 50%, or at least 100%, or up to around 300%, or more, than that of the soft photoresist material. This may allow the patterned hardmask layer 327 to be optionally thinner than the thick photoresist layer 207, while still preventing penetration of the additional dopant 331 into the unintended regions of the semiconductor substrate to the same degree. By way of example, the thickness of a silicon dioxide layer may be between about one third to two thirds the thickness of a photoresist layer that would be needed to provide the same masking ability. Using a thinner hardmask layer may facilitate patterning of smaller dimensioned openings.

The method of forming the doped isolation region 332 shown in FIGS. 3A-3H may offer one or more advantages over the method shown in FIGS. 2A-2C. For one thing, since the thin patterned photoresist layer 325 of FIG. 3E does not need to be thick to stop the additional dopant 331, it may optionally be significantly thinner than the thick patterned photoresist layer 207 shown in FIG. 2B. It tends to be easier to photolithographically pattern small width openings in such a thin photoresist layer 325 as compared to such a thick photoresist layer 207. This is especially true when the width of the trench or other opening 208 in the photoresist layer approaches 0.4 μm or less and/or when high energy dopant implantations using at least about 1 MeV to several MeV are used. As a result, one potential advantage is the possibility of further size reductions of the opening 328 and/or the doped isolation region 332, which may help to facilitate further pixel size reductions.

Another potential advantage to using the patterned hardmask layer 327 to mask the dopant implantation is that a profile and/or shape of the opening 328 in the hardmask layer may tend to avoid change/deformation or hold up better (e.g., during the initial stages of dopant implantation) than the thick patterned photoresist layer. The hard material of the hardmask layer typically retains the initial desired shape of the opening better than the soft photoresist material. This may help to reduce unintended changes in dopant concentrations and/or unintended shape changes of the doped isolation region 332.

Yet another potential advantage to using the patterned hardmask layer 327 to mask the dopant implantation, as compared to using the thick photoresist layer 207, is that the dopant implantation may tend to make the photoresist relatively difficult to remove, whereas the patterned hardmask layer may remain easy to remove after dopant implantation.

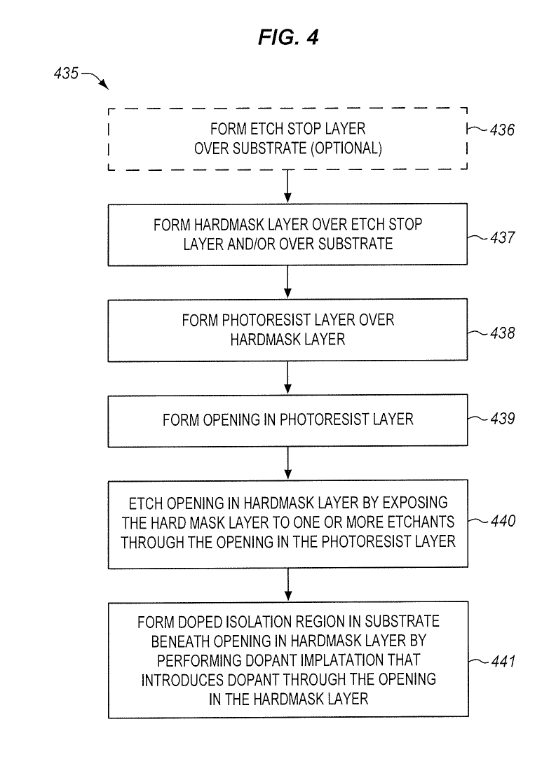

FIG. 4 is a block flow diagram of an example embodiment of a method 435 of forming a doped isolation region in a substrate. In embodiments of the invention, the method may be performed during a method of manufacturing an image sensor.

The method may include forming an optional etch stop layer over the substrate, at block 436. Forming the etch stop layer is optional and not required.

A hardmask layer is formed over the etch stop layer, at block 437. The hardmask layer may have the attributes of the hardmask layer 323 previously discussed above. In some embodiments, the hardmask layer may include, predominantly include, or be a hard, inorganic, potentially amorphous, solid material, which is harder than a comparatively soft resist material. In some embodiments, the hardmask layer may be a layer of an oxide of a semiconductor (e.g., an oxide of silicon) or a semiconductor (e.g., polysilicon), although the scope of the invention is not so limited. For the aforementioned types of materials, in some embodiments, the previously formed etch stop layer may include a nitride of a semiconductor (e.g., a nitride of silicon).

A photoresist layer is formed over the hardmask layer, at block 438. The photoresist layer may optionally be formed thin, or at least thinner than the thick photoresist layer 207 mentioned in regard to FIG. 2B.

At block 439, an opening is patterned or formed in the photoresist layer. Without limitation, in some embodiments, a width of the opening may be less than about 0.4 μm, less than about 0.3 μm, less than about 0.25 μm, or less than about 0.2 μm. For example, in one embodiment, the width W2 may range between about 0.2 μm to about 0.4 μm. However, the scope of the invention is not limited to forming such small openings.

An opening is etched or formed in the hardmask layer by exposing the hardmask layer to one or more etchants or an etching medium through the opening in the photoresist layer, at block 440. This may include exposing or contacting a surface of the hardmask layer exposed by, and coextensive with, the opening formed in the photoresist layer, to one or more etchants that may etch away portions of the hardmask layer. Then, the patterned photoresist layer may optionally be removed, if desired.

The doped isolation region is formed in the substrate beneath the opening etched in the hardmask layer by introducing dopant through the opening in the hardmask layer, at block 441. In some embodiments the doped isolation region is formed by performing a high energy dopant implantation. The patterned hardmask layer may stop dopant introduced at locations other than the opening so that the dopant is prevented from entering unintended regions of the substrate.

Advantageously, the profile of the opening in the hardmask layer may be retained throughout the dopant implantation better than that of the opening in the photoresist used in a known doped isolation region formation process. Further, the dopant implantation does not make removal of the hardmask layer difficult, which tends to be the case for photoresists.

The method 435 has been described in a relatively basic form, although operations may optionally be added to and/or removed from the method. For example, the formation of the etch stop may be omitted, an additional operation of removing the photoresist layer after formation of the opening in the hardmask layer prior to the dopant implantation may be added, etc. Many modifications and adaptations may be made to the method and are contemplated. It is also to be appreciated that inventive methods also lie in subsets of the set of operations of the illustrated example method 435.

Moreover, other operations associated with image sensor formation may be added to the method. For example, trenches may be formed in the semiconductor substrate and the trenches may be filled with an insulating or dielectric material to form shallow trench isolation (STI), deep trench isolation (DTI), or other trench isolations. Other operations may include planarization by way of chemical mechanical polishing, gate oxidation, ion implantation, polysilicon deposition, and etching. As shown in the illustrated embodiments, in some embodiments, the trench isolation may be formed after the formation of the doped isolation regions such that the trenches are formed into the doped isolation regions. Alternatively, in other embodiments, the trench isolation may be formed before the formation of the doped isolation regions, such that dopant implantation is performed into and/or through the trenches. Alternatively, doped isolation regions may be used without trench isolation, although commonly trench isolation will be included in order to help increase the amount of isolation. Another example of operations that may be added to the methods is formation of photosensitive elements (e.g., photodiodes) and/or other portions of pixels adjacent to or on opposite sides of the doped isolation regions. In some embodiments, the pixels may be 1.75 μm or smaller pixels, or 1.4 μm or smaller pixels, although the scope of the invention is not so limited.

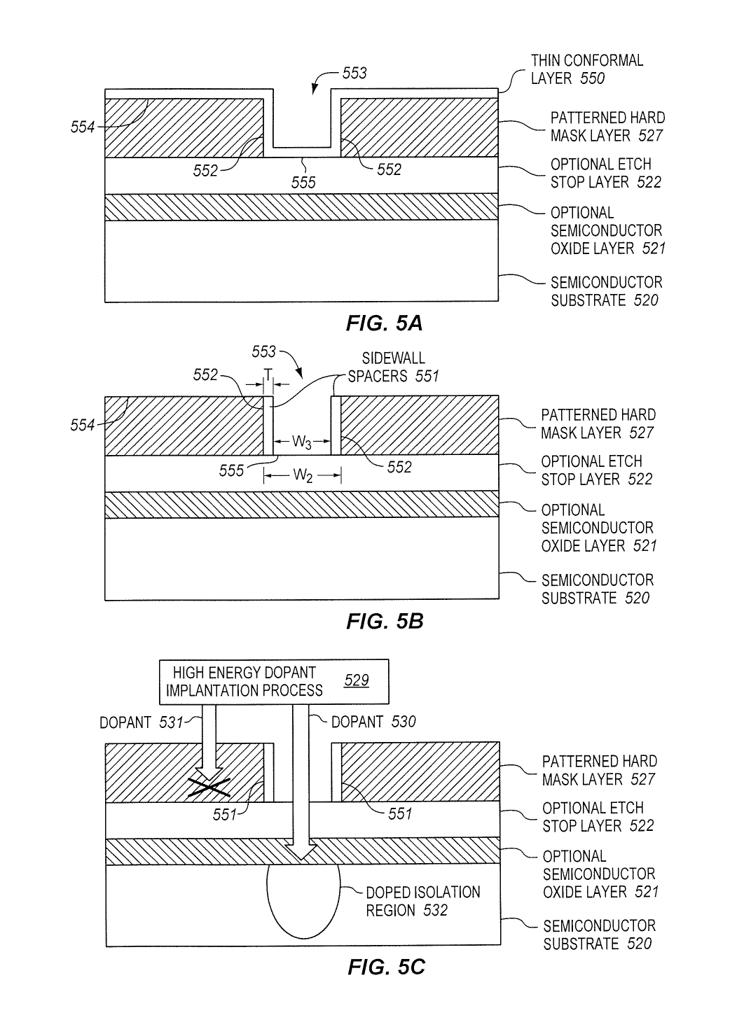

As mentioned above, in some embodiments, the approaches shown in FIGS. 3-4 may be used to reduce the size of the openings through which dopant is introduced into the substrate, the size of the doped isolation regions, and/or the size of the pixels. If desired, the size of the openings, the doped isolation regions, and/or the pixels may optionally be further reduced by the approach illustrated in FIG. 5A-5C. However, it is to be appreciated that the scope of the invention is not limited to forming small openings, doped isolation regions, or pixels. Rather, the approaches shown in FIGS. 3-5 are also useful to avoid changes in the profiles of the open openings through which dopant is introduced into the substrate and/or to avoid the need to perform a difficult removal of photoresist following a dopant implantation.

FIGS. 5A-5C are cross-sectional side views of substrates representing different stages of an example embodiment of a method of forming a doped isolation region 532 in a semiconductor substrate 520. In this embodiment, the method includes forming sidewall spacers 551 on vertical sidewalls 552 of a trench or other opening 553. The sidewall spacers are formed on the vertical sidewalls of the opening prior to forming the doped isolation region through a dopant implantation process 529 that uses the sidewall spacers to help narrow the region into which the dopant is introduced into the semiconductor substrate.

FIG. 5A shows depositing or otherwise forming a thin generally conformal layer 550 over a patterned layer 527 having the trench or other opening formed therein. The thin generally conformal layer is deposited over a top surface 554 of the patterned layer, on vertical sidewalls 552 of the opening, and on a bottom surface 555 of the opening.

In the illustrated embodiment, the thin conformal layer 550 is deposited or otherwise formed over a patterned hardmask layer 527 of a substrate, which is similar to, or the same as, the substrate of FIG. 3G, although the scope of the invention is not so limited. The substrate includes a semiconductor substrate 520, an optional thin semiconductor oxide layer 521, an optional etch stop layer 522, and the patterned hardmask layer 527. These components may have the same characteristics as those previously described. As shown, the thin conformal layer may be disposed on (e.g., abut or contact) the patterned hardmask layer. In other embodiments, the thin conformal layer may be deposited over an entirely different patterned layer and/or an entirely different substrate.

In some embodiments, the thin conformal layer 550 may include a relatively “hard” material that is relatively harder than a “soft” organic polymeric material typically used for a photoresist. Typically, the thin conformal layer includes, is predominantly, or is substantially all, inorganic solid material. The inorganic solid material may be amorphous, crystalline, or a combination of amorphous and crystalline. In one embodiment, a substantially amorphous material may be used in order to better stop implantation of dopant. As used herein, a substantially amorphous material is one having less than 30% crystallinity by volume.

Examples of suitable materials for the thin conformal layer 550 include, but are not limited to, semiconductors (e.g., silicon), amorphous semiconductors (e.g., polysilicon or amorphous silicon), oxides of semiconductors (e.g., silicon dioxide and other oxides of silicon), nitrides of semiconductors (e.g., silicon nitride and other nitrides of silicon), oxy-nitrides of semiconductors (e.g., oxy-nitrides of silicon), metals, metal oxides, metal nitrides, metal oxy-nitrides, and combinations thereof. In some embodiments, the material of the thin conformal layer may include one or more of an oxide of silicon or other semiconductor (e.g., silicon dioxide), a nitride of silicon or other semiconductor (e.g., silicon nitride), an oxy-nitride of silicon or other semiconductor (e.g., silicon oxy-nitride), an amorphous semiconductor (e.g., polysilicon), and combinations thereof. In some cases, the material of the thin conformal layer 550 may optionally be the same as the material of the patterned hardmask layer 527 so that a single process may be used to remove both the thin conformal layer and the patterned hardmask layer.

In some embodiments, the thin conformal layer 550 may be deposited by atomic layer deposition (ALD). Advantageously, the use of ALD may allow potentially very thin and very conformal layers to be deposited with relatively precise control over the thickness of the deposited layer. Alternatively, other methods of deposition, such as, for example, chemical vapor deposition (CVD) or physical vapor deposition (PVD), may optionally be used. In yet another embodiment, the patterned hardmask layer 527 may include a semiconductor material (e.g., polysilicon or silicon), and the thin conformal layer 550 may be a grown layer (e.g., a grown oxide of silicon or other semiconductor) that is grown rather than deposited.

FIG. 5B shows optionally removing portions of the thin conformal layer 550 from over the top surface 554 of the patterned hardmask layer 527 and from over the bottom surface 555 of the opening 553. As shown, portions of the thin conformal layer 550 are allowed to remain on the vertical sidewalls 552 of the opening as the sidewall spacers 551. Removing the portion of the thin conformal layer from over the bottom surface of the opening may help to avoid the need to implant dopant 530 through this portion, which may help to allow the dopant to be implanted deeper into the semiconductor substrate. However, removing these portions of the thin conformal layer is optional and not required.

In some embodiments, the portions of the deposited thin conformal layer may be removed by performing an anisotropic etch or other orientation dependent etch, which may etch faster or preferentially in a vertical direction than in a horizontal direction, as viewed. For example, an anisotropic plasma etch, such as a reactive ion etch (RIE), may be used. The RIE may represent a dry-etch process that may use electrical discharge to create ions and induce ion bombardment of the horizontal surfaces of the thin conformal layer in order to etch these horizontal surfaces. Alternatively, other anisotropic etches or other orientation dependent etches may be used.

Advantageously, the sidewall spacers 551 may help to narrow a cross-sectional width (W3) or dimension of the opening 553, which in some embodiments may be used to form very narrow openings. The thin conformal layer effectively adds material alongside the sidewalls of the opening. The thin conformal layer may narrow the width of the opening by about two times the thickness of the sidewall spacers (or the deposited layer if there is no etching in the horizontal direction). In some embodiments, the starting cross-sectional width (W2) of the starting opening (see also e.g., the width W2 shown in FIG. 3F) may be less than 0.4 μm, and the thickness (T) of the sidewall spacers 551 may be sufficient to give a resulting cross-sectional width (W3) of a resulting opening that is less than 0.2 μm, although the scope of the invention is not so limited. In some embodiments, a starting cross-sectional width (W2) of the starting opening may be less than 0.4 μm or 0.3 μm, and the thickness of the sidewall spacers 551 may range from about 5 nanometers (nm) to about 100 nm, or from about 20 nm to about 70 nm, or from about 30 nm to about 60 nm, although the scope of the invention is not so limited. In some embodiments, resulting widths of the resulting openings due to the sidewall spacers are less than about 0.25 μm, or less than about 0.2 μm, although the scope of the invention is not so limited. As one particular example, a starting opening with a starting width of about 0.2 μm may be reduced to a resulting width of about 0.1 μm with a thin conformal deposited layer having a thickness of about 50 nm. In some embodiments, the resulting openings may have very narrow widths that cannot be achieved, or cannot be practically achieved, through a given lithography and etching process used to pattern the initial openings.

FIG. 5C shows forming the doped isolation region 532 in the semiconductor substrate 520 beneath the opening 553 in the patterned hardmask layer 527 by performing a dopant implantation that introduces dopant through the opening 553 in the patterned hardmask layer 527. In some embodiments, a high energy dopant implantation process 529 may be used to implant dopant 530 into the doped isolation region through the opening 553 in order to from the doped isolation region deeply below the top surface of the semiconductor substrate. The patterned hardmask layer may stop additional dopant 531 from entering unintended regions of the semiconductor substrate, as previously described. The sidewall spacers 551 at least partly determine the region of the top surface of the semiconductor substrate where dopant may be introduced without needing to go through remaining portions of the thickness of the patterned hardmask layer 527.

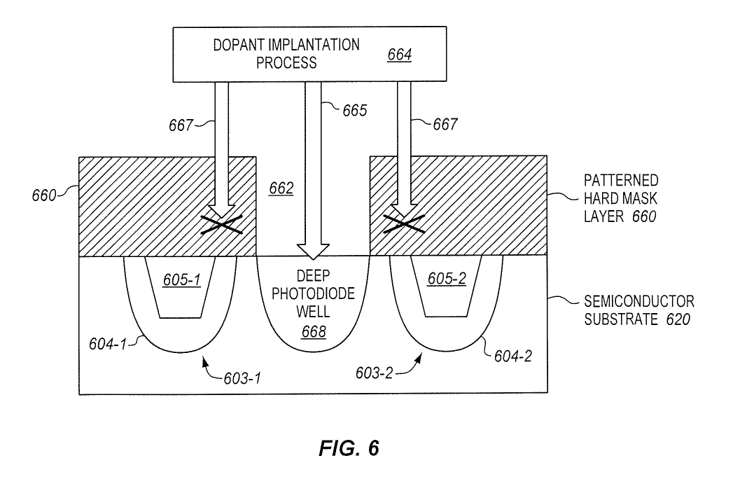

FIG. 6 is a cross-sectional view of a substrate showing an example embodiment of a use of a patterned hardmask layer 660 as a dopant implantation mask when doping a semiconductor substrate 620 to form a deep doped well 668 (e.g., a deep n-type doped well) of a photodiode. Already formed within the semiconductor substrate are a first isolation region 603-1 and a second isolation region 603-2. The first isolation region has a first doped isolation region 604-1 and a first trench isolation 605-1. The second isolation region has a second doped isolation region 604-2 and a second trench isolation 605-2. The doped isolation regions may optionally be performed as previously described, although this is not required. The patterned hardmask layer is formed over the semiconductor substrate. The patterned hardmask layer may have characteristics similar to or the same as those previously described (e.g., same materials, thicknesses, etc.) If desired, other layers (not shown) may optionally be included between the semiconductor substrate and the patterned hardmask layer, such as, for example, an optional etch stop layer.

The patterned hardmask layer has an opening 662 etched or otherwise formed therein by a process similar to that previously described, for example by depositing a photoresist layer, lithographically patterning and developing an etch mask opening in the photoresist layer, and etching the hardmask layer using the etch mask opening. A dopant implantation process 664 is used to introduce dopant 665 into the semiconductor substrate through the opening in the patterned hardmask layer. The patterned hardmask layer prevents implantation of additional dopant 667 into unintended regions of the substrate (e.g., the isolation regions 603). Advantageously, compared to a patterned photoresist layer, the vertical sidewalls of the patterned hardmask layer used as a dopant implantation mask are less likely to fall, slump, other otherwise change their profile. Moreover, compared to a patterned photoresist layer, the patterned hardmask layer is less likely to fail to adhere to underlying layers and/or easier to be removed following the doping.

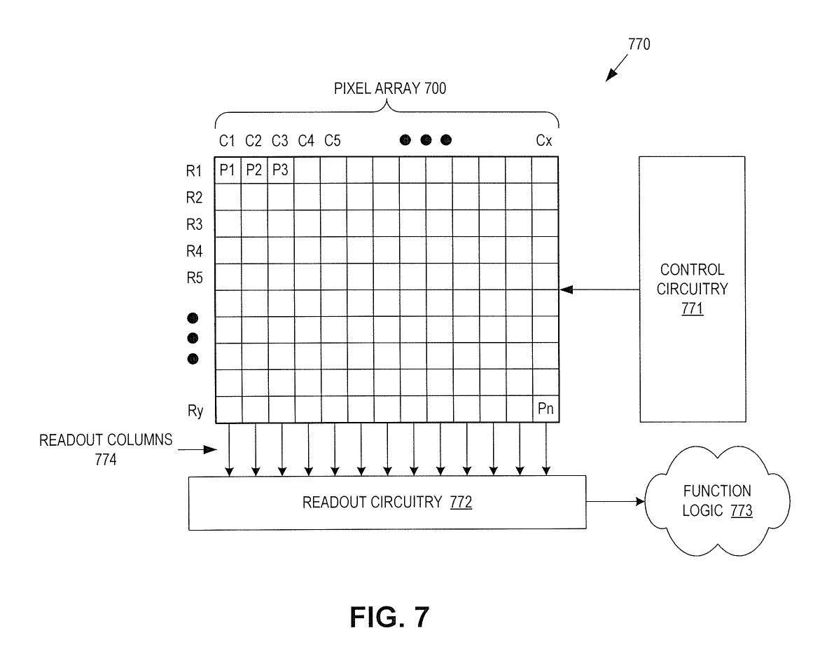

FIG. 7 is a block diagram of an example embodiment of an image sensor system 770. The illustrated embodiment of the image sensor system includes a pixel array 700, readout circuitry 772, function logic 773, and control circuitry 771. The pixel array or image sensor array includes a two-dimensional array of pixels (e.g., pixels P1, P2, P3, . . . Pn). As illustrated, the pixels of the image sensor array are arranged into rows (e.g., rows R1 through Ry) and columns (e.g., column C1 through Cx). Commonly there are numerous rows and numerous columns. During image acquisition, each of the pixels may acquire image data (e.g., an image charge). In one embodiment, each pixel is a complementary metal oxide semiconductor (CMOS) pixel. In another embodiment, each pixel is a charge coupled device (CCD) type pixel. The image sensor array may be implemented as either a front side illuminated (FSI) image sensor array or a backside illuminated (BSI) image sensor array. The image sensor array may be either color or black and white. The image sensor array may be used to acquire image data (e.g., 2D images and/or video).

After each pixel has acquired its image data or image charge, the image data is readout by the readout circuitry 772 and transferred to the function logic 773. The readout circuitry may readout a row of image data at a time along readout column lines 774, or readout the image data using column readout, serial readout, full parallel readout of all pixels concurrently, etc. In one aspect, the function logic may merely store the image data, or in another aspect the function logic may manipulate the image data using various ways known in the arts (e.g., crop, rotate, remove red eye, adjust brightness, adjust contrast, etc). The function logic may be implemented in hardware, software, firmware, or a combination. The control circuitry 771 is coupled to the pixel array to control operational characteristics of the pixel array. For example, the control circuitry may generate a shutter signal for controlling image acquisition. The shutter signal may be a global shutter signal or a rolling shutter signal.

In the description above, for the purposes of explanation, numerous specific details have been set forth in order to provide a thorough understanding of the embodiments of the invention. It will be apparent however, to one skilled in the art, that one or more other embodiments may be practiced without some of these specific details. The particular embodiments described are not provided to limit the invention but to illustrate it. It will also be appreciated, by one skilled in the art, that modifications may be made to the embodiments disclosed herein, such as, for example, to the sizes, shapes, configurations, forms, functions, materials, of the components of the embodiments. The scope of the invention is not to be determined by the specific examples provided above but only by the claims below.

In other instances, well-known structures, devices, and operations have been shown in block diagram form or without detail in order to avoid obscuring the understanding of the description. For simplicity and clarity of illustration, elements illustrated in the figures have not necessarily been drawn to scale. For example, the dimensions of some of the elements are exaggerated relative to other elements for clarity. Further, where considered appropriate, reference numerals or terminal portions of reference numerals have been repeated among the figures to indicate corresponding or analogous elements, which may optionally have similar characteristics.

It should also be appreciated that reference throughout this specification to “one embodiment”, “an embodiment”, or “one or more embodiments”, for example, means that a particular feature may be included in the practice of the invention. Similarly, it should be appreciated that in the description various features are sometimes grouped together in a single embodiment, Figure, or description thereof for the purpose of streamlining the disclosure and aiding in the understanding of various inventive aspects. This method of disclosure, however, is not to be interpreted as reflecting an intention that the invention requires more features than are expressly recited in each claim. Rather, as the following claims reflect, inventive aspects may lie in less than all features of a single disclosed embodiment. Thus, the claims following the Detailed Description are hereby expressly incorporated into this Detailed Description, with each claim standing on its own as a separate embodiment of the invention.

What is claimed is:

1. A method of forming a doped isolation region in a substrate during manufacture of an image sensor, the method comprising:
forming a hardmask layer over the substrate;
forming a photoresist layer over the hardmask layer;
forming an opening in the photoresist layer, wherein the opening is formed over an intended location of a doped isolation region;
etching an opening in the hardmask layer by exposing the hardmask layer to one or more etchants through the opening in the photoresist layer, wherein etching the opening in the hardmask layer includes etching an opening in the hardmask layer that has a width that is less than 0.4 micrometers; and
forming the doped isolation region in the substrate beneath the opening in the hardmask layer by performing a dopant implantation that introduces dopant through the opening in the hardmask layer.

2. The method of claim 1, wherein forming the hardmask layer comprises forming a hardmask layer comprising a predominantly amorphous inorganic material.

3. The method of claim 2, wherein forming the hardmask layer comprises forming a layer comprising at least one material selected from a group consisting of a substantially amorphous silicon, a polysilicon, an oxide of silicon, a nitride of silicon, an oxy-nitride of silicon, and a glass.

4. The method of claim 1, further comprising, prior to forming the hardmask layer, forming an etch stop layer over the substrate, and wherein forming the hardmask layer comprises forming the hardmask layer over the etch stop layer.

5. The method of claim 4, wherein forming the etch stop layer comprises forming a layer including a nitride of silicon, and wherein forming the hardmask layer comprises forming a layer including at least one of an oxide of silicon and polysilicon.

6. The method of claim 1, wherein etching the opening in the hardmask layer comprises etching a trench in the hardmask layer that has a width that is less than 0.3 micrometers.

7. The method of claim 1, further comprising, after said etching the opening in the hardmask layer, and before said forming the doped isolation region in the substrate, forming sidewall spacers on sidewalls of the opening in the hardmask layer.

8. The method of claim 7, wherein forming the sidewall spacers comprises depositing material by atomic layer deposition (ALD).

9. The method of claim 7, wherein forming the sidewall spacers comprises:
depositing a layer over a top surface of the hardmask layer, over the sidewalls of the opening in the hardmask layer, and on a bottom surface of the opening in the hardmask layer; and
removing portions of the deposited layer from over the top surface of the hardmask layer and on the bottom of the opening in the hardmask layer.

10. The method of claim 7, wherein etching the opening in the hardmask layer comprises etching an opening that has a width that is less than 0.3 micrometers, and wherein forming the sidewall spacers comprises forming a thickness of the material that ranges from 5 to 100 nanometers.

11. The method of claim 7, wherein forming the sidewall spacers comprises forming sidewall spacers with a width sufficient to give a resulting width of a resulting opening in the hardmask layer that is less than 0.2 micrometers.

12. The method of claim 1, wherein performing the dopant implantation comprises implanting dopant into the region with an energy of at least about one million electron volts.

13. The method of claim 1, further comprising forming a trench in the substrate over the doped isolation region, and substantially filling the trench with an insulating material.

14. The method of claim 1, further comprising forming an array of photodiodes in the substrate.

15. A method of forming a doped isolation region in a substrate during manufacture of an image sensor, the method comprising:
forming a hardmask layer including an inorganic solid material over the substrate;
forming a photoresist layer over the hardmask layer;
patterning an opening in the photoresist layer, the opening having a width that is less than 0.4 micrometers, the opening over an intended location of the doped isolation region;
etching an opening in the hardmask layer by exposing the hardmask layer to an etching medium through the opening in the photoresist layer;
removing the photoresist layer;
forming the doped isolation region in the substrate beneath the opening in the hardmask layer by performing a high energy dopant implantation that introduces dopant through the opening in the hardmask layer, the high energy dopant implantation using at least about one million electron volts; and
forming a photodiode in the substrate adjacent to the doped isolation region.

16. The method of claim 15, wherein forming the hardmask layer comprises forming a layer comprising at least one material selected from amorphous silicon, polysilicon, an oxide of silicon, a nitride of silicon, an oxy-nitride of silicon, and a glass.

17. The method of claim 15, further comprising, after said etching the opening in the hardmask layer, and before said forming the doped isolation region in the substrate, forming sidewall spacers on sidewalls of the opening in the hardmask layer.

18. An apparatus comprising:
a semiconductor substrate;
a doped isolation region within the semiconductor substrate;
a patterned hardmask layer over the substrate;
an opening defined within the patterned hardmask layer, the opening over the doped isolation region, the opening defined within the patterned hardmask layer having a width of less than 0.4 micrometers, where the doped isolation region includes dopant introduced into the semiconductor substrate through the opening defined within the patterned hardmask layer.

19. The apparatus of claim 18, wherein the patterned hardmask layer comprises a predominantly inorganic solid material.

20. The apparatus of claim 18, further comprising sidewall spacers on sidewalls of the opening in the hardmask layer.
